(19) United States
(12) Patent Application Publication
(10) Pub. No.: US 2013/0240847 A1
(43) Pub. Date: Sep. 19, 2013

(54) MONOLITHIC PARALLEL MULTIJUNCTION OLED WITH INDEPENDENT TUNABLE COLOR EMISSION

(71) Applicants: Anvar A. Zakhidov, McKinney, TX (US); Alexios Papadimitratos, McKinney, TX (US)

(72) Inventors: Anvar A. Zakhidov, McKinney, TX (US); Alexios Papadimitratos, McKinney, TX (US)

(73) Assignees: Solarno, Inc., Coppell, TX (US); The Board of Regents of the University of Texas System, Austin, TX (US)

(21) Appl. No.: 13/698,858

(22) PCT Filed: May 21, 2011
(86) PCT No.: PCT/US2011/037481

§ 371 Date: May 30, 2013

Related U.S. Application Data
(60) Provisional application No. 61/347,272, filed on May 21, 2010.

(51) Int. Cl. H01L 51/52; H01L 51/56

(52) U.S. Cl. CPC H01L 51/5203; H01L 51/56; B82Y 40/00
USPC 257/40; 257/88; 438/46; 977/742; 977/842

(57) ABSTRACT

A tandem organic light emitting diode (OLED) device comprised of multiple stacked single OLEDs electrically connected in parallel via transparent interlayer is recited herein. Transparent interlayers are coated by charge injection layers in order to enhance the charge injection efficiency and decrease the operation voltage. Transparent nanomaterials, such as carbon nanotube sheets (or graphene, graphene ribbons and similar conductive transparent nano-carbon forms) are used as Interlayers or outer electrodes. Furthermore, functionalization of carbon nanotubes inter layers by n-doping (or p-doping) converts them into common cathode (or common anode), further decreasing operation voltage of tandem. The development of these alternative interconnecting layers comprised of nanomaterials simplifies the process and may be combined with traditional OLED devices. In addition, novel architectures are enabled that allow the parallel connection of the stacked OLEDs into monolithic multi-junction OLED tandems.

### CROSS-REFERENCES TO RELATED APPLICATIONS

This application claims priority from U.S. Provisional Patent Application No. 61/347,272 filed May 21, 2010, which is hereby incorporated by reference as if fully set forth herein.

### STATEMENT REGARDING FEDERALLY-SPONSORED RESEARCH OR DEVELOPMENT

This invention was made with government support under Grant No. DE-SC0001145 and Grant No. DE-SC0003664 awarded by the Department of Energy. The government has certain rights in the invention.

### BACKGROUND OF INVENTION

An organic light-emitting diode device, also called an OLED, commonly includes an anode, a cathode, and an organic electroluminescent (EL) unit sandwiched between the anode and the cathode. Generally, at least one of the electrodes is transparent. The organic EL unit may be comprised of a single electroluminescent material in the case of polymer based OLEDs. Also, in the case of small molecule OLEDs it may include a hole-transporting layer (HTL), a light-emitting layer (EML), and an electron-transporting layer (ETL). Both small molecular and polymer based OLED devices have been recognized as promising display and solid state lighting (SSL) technologies. Commonly used molecules include organo-metallic chelates such as Tris(8-hydroxyquinolinato)aluminium (Alq3) and conjugated dendrimers. It has been demonstrated that multilayer small molecular OLEDs can be fabricated by vacuum thermal evaporation of these molecules. It was later demonstrated that the first polymer light-emitting diodes (PLED) involve an electroluminescent conductive polymer that emits light when connected to an external voltage source. Typical polymers used in PLEDs include derivatives of poly (p-phenylene vinylene) (PPV) and polyfluorene (PFO). Substitution of side chains onto the polymer backbone determine the color of emitted light.

Recently developed tandem structure OLEDs consisting of multiple electroluminescent units connected in series have shown enhancement in brightness and in efficiency. However, such structures require a complex interfacial layer between two emissive layers EML (1) and EML (2) which is critical for the device operation. The improved efficiency for a tandem OLED compared to traditional OLED can only be achieved if the intermediate connector has excellent charge injection capabilities and negligible voltage drop across it. Many improved interconnecting layers in tandem OLEDs have been tried, such as Mg:Ag/indium zinc oxide, Mg:Alq₃/WO₃, Bphen:Li/MoO₃, Li₂O etc. However, the fabrication of an interlayer between EML (1) and EML (2) requires delicate vacuum handling and either evaporation or sputtering processes. Inevitably, the fabrication process becomes increasingly complicated.

Thus, there is a need for a tandem OLED with low voltage operation (as compared to existing in-series tandems) and capability to tune colors independently that can be made using a simplified fabrication process.

### SUMMARY OF THE INVENTION

An embodiment of the claimed invention is directed to a parallel tandem OLED architecture with transparent nanomaterial, such as carbon nano-structures (carbon nanotubes (CNT), graphene, and similar nano-C) sheets as interconnecting interlayer, properly combined with charge injection layers from both sides to it. The CNT sheets, used as an example of an interlayer, can either be single wall carbon nanotube (SWCNT) sheets, multi wall carbon nanotube (MWCNT) sheets, graphene, and other graphene derivatives. The OLED tandem device structure comprises several stacked electroluminescent units connected electrically in parallel. At the heart of the design is an interconnecting electrode, consisting of tunable blend of transparent conductive nano-C structures with appropriate electrical and optical properties. This nano-C structure interlayer electrode, particularly CNT, are either in pristine condition, doped (by p-type or n-type dopants) or utilize conversion layers adjacent to it, called charge injection layers. The heterojunction between charge injection layers (hole injection layer (HTL) or electron injection layer (ETL)) and the emissive layers improve the device performance, lowering operating voltage and increasing the injection current and facilitate fabrication.

Parallel tandem OLEDs of the claimed invention have high intensity optical output whose color is a linear superposition of spectra of the individual emitting elements in the device. White light OLEDs are constructed by mixing of two or more complimentary colors (electroluminescent units). The units are placed in a vertically stacked geometry to provide a simple fabrication process and high resolution display capability. The present approach of a parallel tandem possess all of the advantages of the stacked OLED and at the same time introduce a series of new advantages because of the proposed parallel configuration, as compared to conventional in-series tandems. The fabrication of white OLEDs is possible by combinations of the two or more subunit EMLs with complimentary colors in parallel connection. White light can be produced by a combination of blue, red and green light simultaneously. The design of parallel tandem OLEDs may be applied to achieve tunable light emission of any color (by separate voltage applied to each subunit) by combining the appropriate subunits with the appropriate active organic layers.

Embodiments of the claimed invention are directed to the application of nano-carbon structures (such as transparent CNT sheets) in parallel tandem OLEDs. A transparent CNT sheet forms an interlayer between the top OLED and transparent bottom OLED units. The claimed invention has the subunits of the tandem in parallel electrical connection architecture with an interlayer serving as a functional active third electrode that is common for both subunits. The present concept is not limited to a tandem OLED comprising only two subunits but may be extended to multi-unit tandems, consisting of three, four or any number of multiple subunits.

The functional character of a common electrode or transparent interlayer comprising materials such as the CNT, capable of injecting high currents of required polarity is provided by one of three methods: 1) by P-type or n-type doping of the nanomaterial; 2) by addition of inversion layers (adjacent to an interlayer electrode) to modify the effective work function of the interlayer and 3) by disposing injection layers adjacent to an interlayer to enhance the charge injection efficiency; all at low operation voltage.

### BRIEF DESCRIPTION OF THE DRAWINGS

FIG. 1 represents (A) Conventional series tandem connection; (B) the concept of a parallel tandem with CNT active interlayer as an anode; and (C) the concept of a parallel tandem with CNT active interlayer as a cathode;

FIG. 2 represents (A) typical stacked in series tandem OLED configuration; and (B) the concept of a parallel tandem of the present invention with charge injection layers CNT active interlayer as cathode;

FIG. 3 represents (A) band diagram of in-series tandem OLED, and (B) band diagram of parallel tandem OLED;

FIG. 4 represents (A) an architecture of parallel tandem OLED with CNT interlayer (anode) and (B) an electronic circuit that is equivalent to the architecture in FIG. 4A;

FIG. 5 represents an architecture of tandem parallel OLED with CNT interlayer (cathode) and an electronic circuit that is equivalent to the architecture;

FIG. 6 represents a three junction parallel OLED stack with CNT interlayers;

FIG. 7 represents (A) Conventional OLED with TCO anode; (B) OLED with CNT anode at the bottom and (C) an inverted OLED with CNT anode at the top;

FIG. 8 represents a parallel tandem OLED with blue and yellow emitting subunits and a corresponding chromaticity diagram;

FIG. 9 represents a parallel tandem OLED with green and yellow emitting subunits and a corresponding chromaticity diagram;

FIG. 10 represents a multi junction parallel OLED stack with CNT interlayers;

FIG. 11 illustrates the CNT sheet dry-drawing process from the vertically oriented CNT forest and CNT sheet lamination process on an OLED device or substrate;

FIG. 12 represents a transparent OLED with CNT anode layer (top configuration);

FIG. 13 represents a transparent OLED with CNT anode layer (bottom configuration);

FIG. 14 represents a flexible OLED with a CNT electrode and a pictorial representation of its assembly;

FIG. 15 represents a parallel tandem OLED with subunits that utilize doped charge transport/injection layers and a common cathode CNT interlayer;

FIG. 16 represents a parallel tandem OLED with subunits that utilize doped charge transport/injection layers and a common anode CNT interlayer;

FIG. 17 represents a parallel tandem OLED with subunits that utilize phosphorescent emissive layers of PHOLEDs and a common cathode CNT interlayer;

FIG. 18 represents a parallel tandem OLED with subunits that utilize phosphorescent emissive layers and a common anode CNT interlayer;

FIG. 19 represents a tandem organic light emitting transistor (OLET) with CNT common gate and patterned CNT electrodes (horizontal configuration);

FIG. 20 represents a tandem organic light emitting transistor (OLET) with CNT common gate and patterned CNT electrodes (vertical configuration);

FIG. 21 represents an AC powered parallel tandem OLED, with AC voltage operation; and;

FIG. 22 represents (A) Photograph of MWCNT forest with sheet being drawn from it; (B) SEM image of SWCNT sheet; (C) SEM image of MWCNT sheet densified on substrate; and (D) SEM image of MWCNT sheet with better interconnectivity.

### DESCRIPTION OF EXEMPLARY EMBODIMENTS

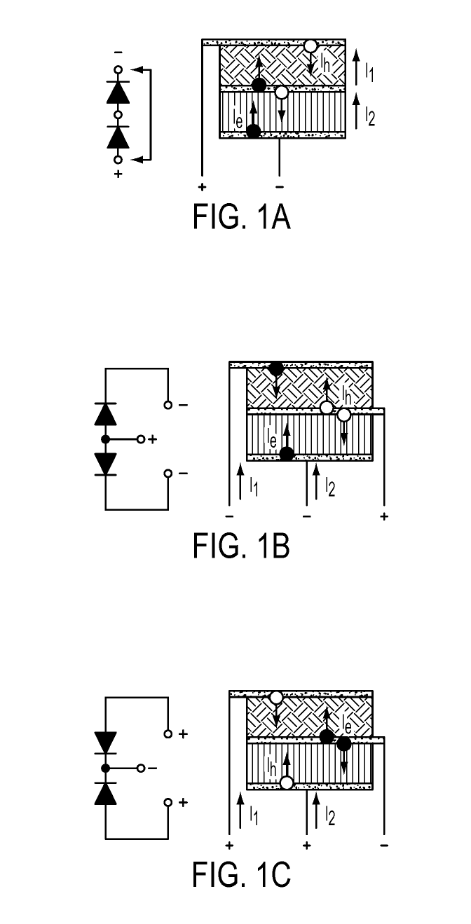

In the in-series connected tandem OLED, the injected holes and electrons are injected from the outer anode and cathode respectively. The injected from anode and cathode carriers are transported through all active materials and recombine with oppositely charged carriers, injected from the interconnecting layer. In this case, the interconnecting layer is a floating electrode, not connected to outside drive electronics. FIG. 1A illustrates the concept of in-series tandem connection where the total current I_{T}=I₁=I₂ flows through the whole device to which a nearly twice higher operation voltage is applied: Vₒₚ=V₁+V₂. The interlayer injects electrons e⁻ up and holes h⁺ down, therefore the interlayer should have bilayer work-functions: low work function on lower side and high work-function on upper side of complex interlayer. Operation of this device at high brightness regimes may require the application of increased voltage and higher non-balanced electrical current compared to traditional OLEDs, increasing the consumed power. The increased current density results in faster device degradation.

In contrast, the current in the parallel tandem OLED configuration of the claimed invention is the sum of the currents of each electroluminescent unit I_{T}=I₁+I₂. In this case, the active interlayer is the anode, as shown in FIG. 1B, which presents the concept of parallel tandem connection and shows an equivalent corresponding electrical diagram. In addition, as shown in FIG. 1C, a parallel tandem OLED with common cathode interlayer is possible as well. Each electroluminescent unit may be driven at a different current density I₁ and I₂, provided by separately applied V₁ and V₂ or in other words, may be operated independently for tuning of the intensity of an emitted light. Due to this separate operation the lifetime of parallel tandem OLED of present is expected to be longer, as opposed to in-series tandems, in which the large total current flows through both sub-OLEDs and eventually degrade them by excess heating. Moreover high operational voltage Vₒₚ=V₁+V₂ requires special drive electronics, and this high Vop might be not compatible with lower voltage of the rest of the whole electronic device. So if in-series tandem OLED is a display for a cell phone (or other device), normally operating at lower voltage, then Vₒₚ required for in-series OLED tandem will need an additional high V power supply.

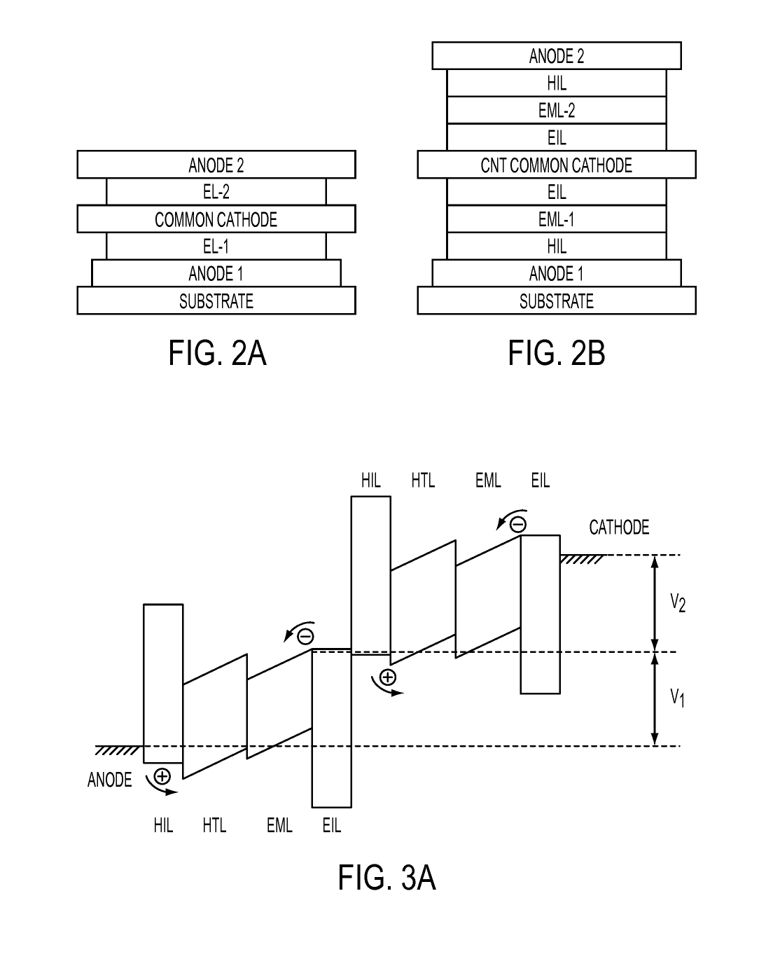

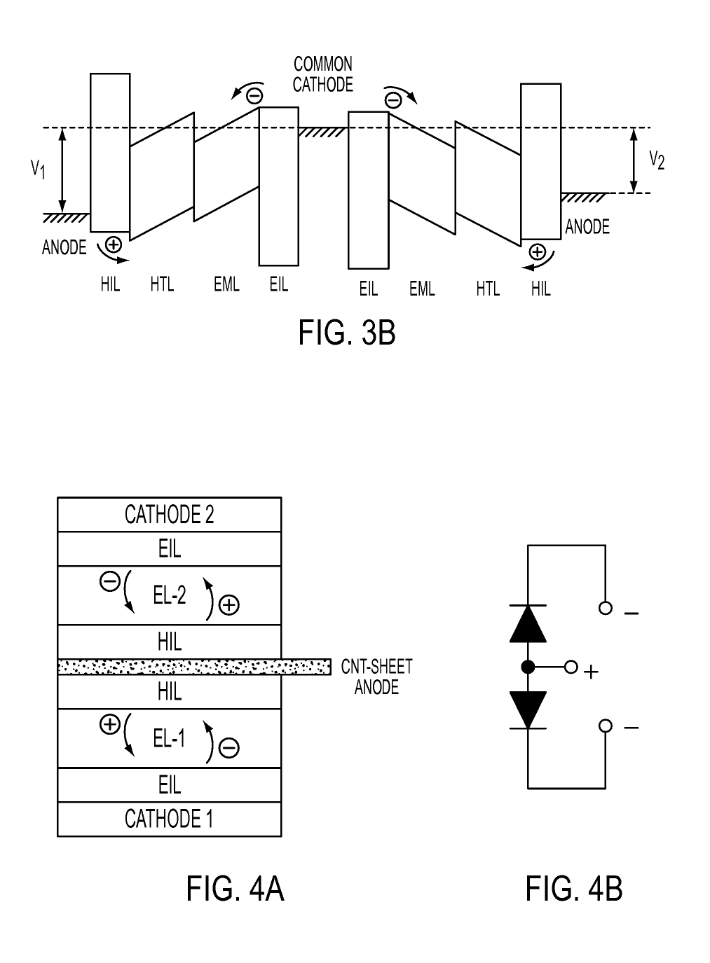

Parallel connection of batteries, organic photovoltaics, OLEDs and other types of devices is not a new concept (FIG. 2A). The claimed invention of parallel tandem OLEDs overcomes disadvantages of previous designs by creating monolithic OLED tandem design comprising additional elements, combined to a simple parallel electrical connection geometry. Previously known stacked tandems OLEDs (in parallel electrical connection) have been reported, but the technology of the claimed invention utilizes multifunctional nano-carbon structures as interlayers with high and properly tuned charge injection properties. The multifunctional nano-carbon structures which can be properly doped themselves or/and by with the proper addition of charge injection and transport layers can realize the new architectures of the claimed invention for enhanced performance and facilitate easier fabrication. The parallel tandem OLED with CNT interlayer of the claimed invention possess at least the following listed advantages compared to an in-series tandem configuration: a transparent interlayer plays a role of either a common cathode (or the common anode) and is an active electrode; operation of parallel tandem is possible at low voltage and thus balanced current density; the increased device stability and lifetime can be obtained; selective operation of each electroluminescent unit is possible by separate voltage control; and each electroluminescent unit may be driven with different current density. For comparison the band diagram of an in-series tandem OLED is shown in FIG. 3A, the stacked geometry and connection type requires high operating voltages. In contrast, in the parallel connection of the top and bottom OLED devices, the operating voltage is expected to be significantly lower (FIG. 3B), due to injection of carriers of same type to both sides of interlayer.

In FIG. 2A, a typical stacked OLED with an interlayer is shown. The interlayer is an active common electrode (i.e. connected to drive electronics, as opposed to a floating, non connected interlayer of in-series connection) as in the parallel tandem OLED architecture that is illustrated in FIG. 2B. To overcome limitations of non-monolithic or stacked tandems, additional functional layers are utilized and attached to the interlayer in a monolithic tandem of the claimed invention.

A device of the claimed invention is built by fabricating a bottom electrode (for example an anode) on top of a substrate. A hole injection layer (HIL) is then deposited prior to the first active layer (EML-1) of the bottom sub unit of the tandem. The interlayer is fabricated with transparent CNT sheets (or other nano-carbon structures in between two electron injection layers (EIL)), built e.g. as n-type doped electron transport layers on both sides of it. The EILs enhance electron injection to the top and bottom sub units of the tandem by converting the CNT interlayer to a common cathode (as shown in FIG. 3). Next, the second electroluminescent material (EML-2) is deposited, followed by the second HIL and the top anode.

FIG. 4A illustrates a parallel tandem OLED with a CNT interlayer that is a common anode for the top and bottom units. As shown in the diagram of the equivalent electrical circuit (FIG. 4B), a positive voltage is applied to the common CNT interlayer anode and a negative voltage to the two cathodes. Electrons are injected through to top and bottom cathodes, while holes are injected through the common anode CNT interlayer into the top and bottom units. The tandem OLED sub units can be fabricated with all known fabrication techniques (solution or vacuum processes). The technology of the claimed invention is not limited to specific polymers but is may be applied to any organic light emitting material that is either fluorescent or phosphorescent.

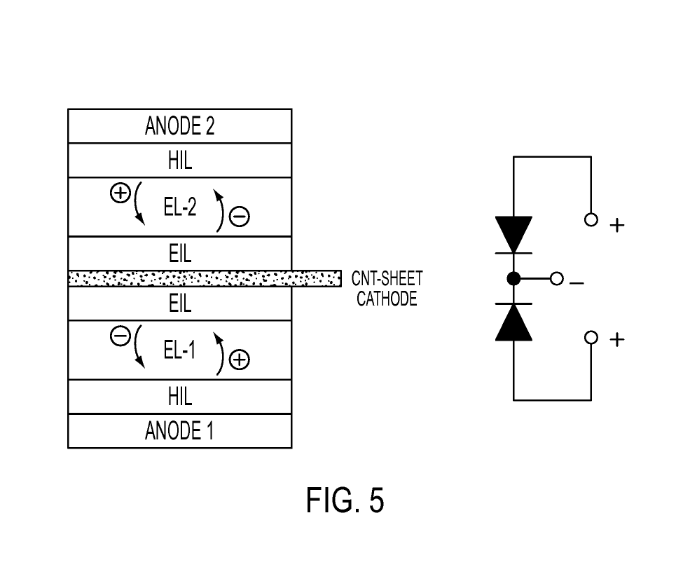

Furthermore, the CNT interlayer may be the common cathode of the tandem. FIG. 5 shows a schematic parallel tandem OLED and the equivalent circuit with a CNT interlayer as common cathode this time. The equivalent circuit shows that a negative voltage is applied to the common CNT interlayer and therefore injecting electrons. At the same time a positive voltage is applied to the two cathodes and holes are injected through to top and bottom anodes. Since, the parallel tandem architecture is not limited to the above light emitting materials, the choice of appropriate injection layers is important when various active layers are used.

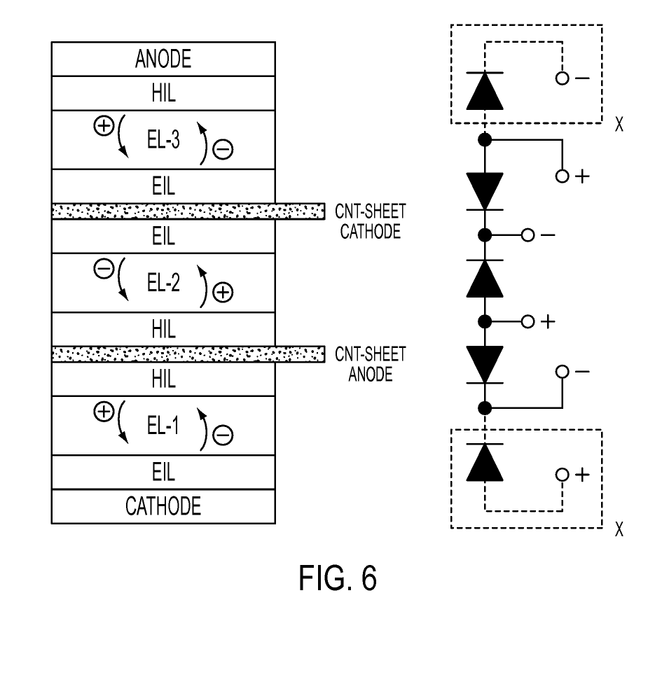

A parallel tandem OLED with three sub-units is shown in FIG. 6. The multifunctional characteristics of the CNT sheets enable the fabrication of such tandem OLEDs. As shown, the bottom electrode is a cathode followed by a bottom active layer. A common anode made of a CNT sheet is placed between a high work function hole injecting and transporting materials to planarize the surface and improve the performance. The middle unit of the parallel tandem OLED has a second emissive layer with different or same light emission wavelength. In contrast to what is expected for the two unit tandem, in this case a second CNT interlayer is deposited instead of the top electrode. The second interlayer functions as a common electrode again but with opposite functionality (in this case a cathode) to the first interlayer in order to provide electrons to the second unit for recombination with injected hole from first interlayer and light emission. Finally, a top anode electrode is fabricated by deposition of a high work metal or oxide. In addition, FIG. 6 illustrates the equivalent circuit of the 3 unit tandem and extension of the concept for more units.

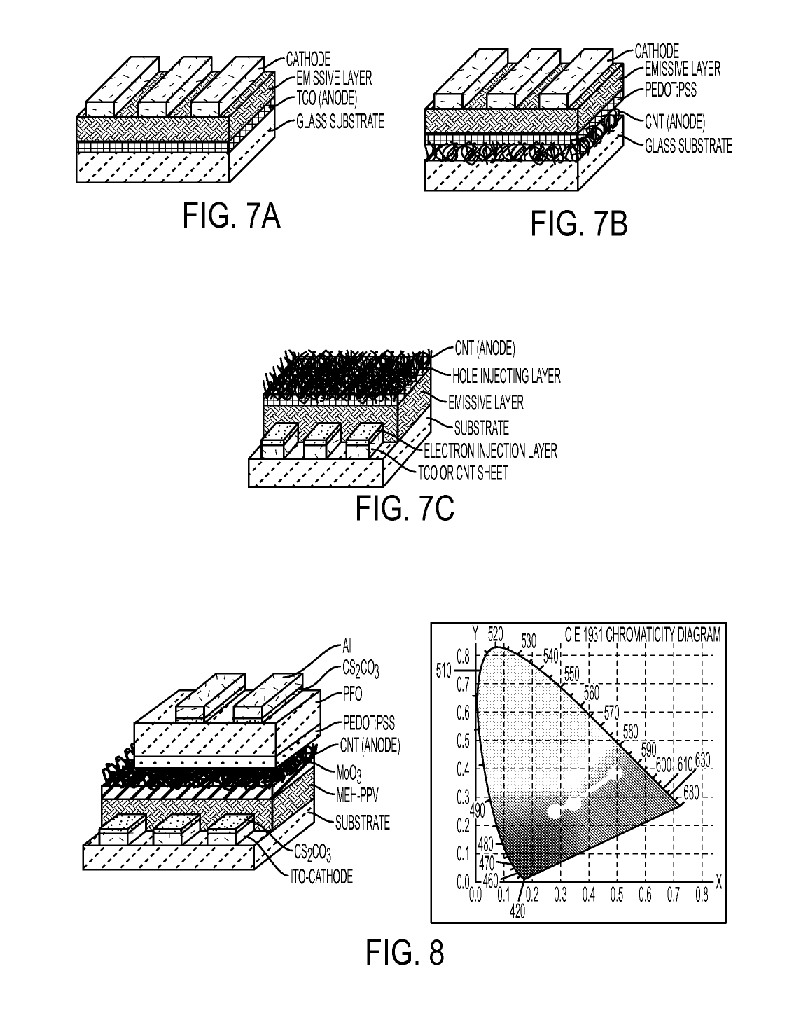

Transparent conductive oxides TCO, such as indium tin oxide (ITO), are traditionally used as anodes in OLEDs. FIG. 7A illustrates the structure of such a simple OLED. An ITO layer is deposited on top of a glass substrate. The organic light emitting material is then deposited by spin casting or thermal evaporation. Finally, the cathode is fabricated by thermal evaporation through a shadow mask. The cathode is usually made from a low work function metal (such as Al or Ag) or a combination of Al and electron injecting layer (EIL) such as LiF, Ca, ZnO or Cs₂CO₃.

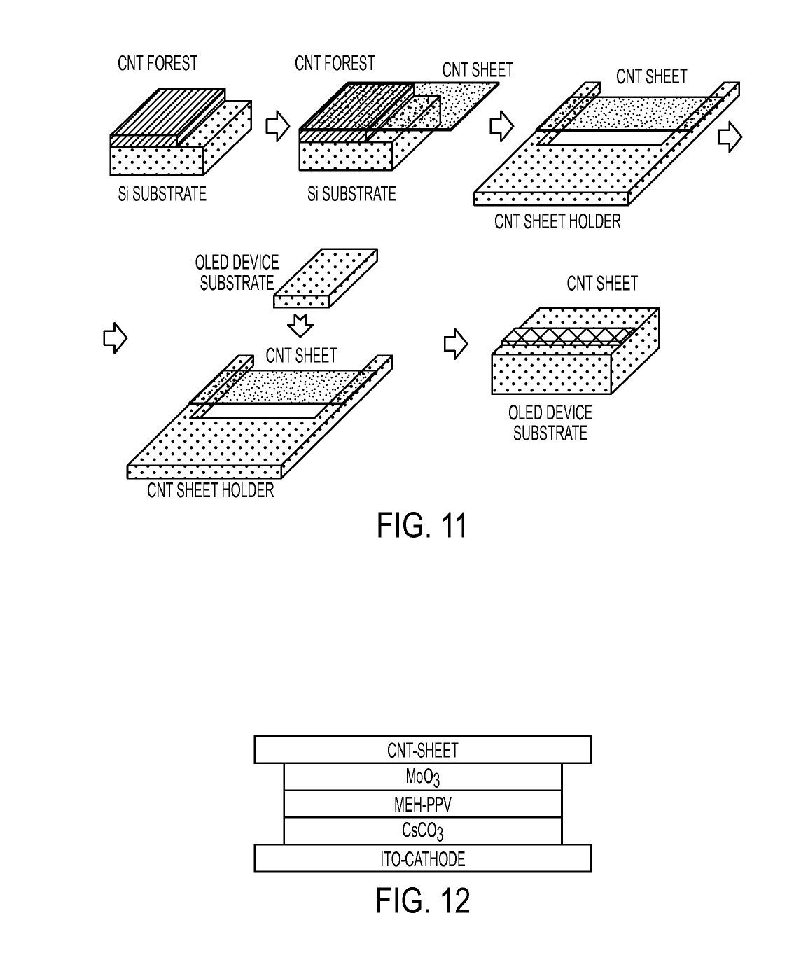

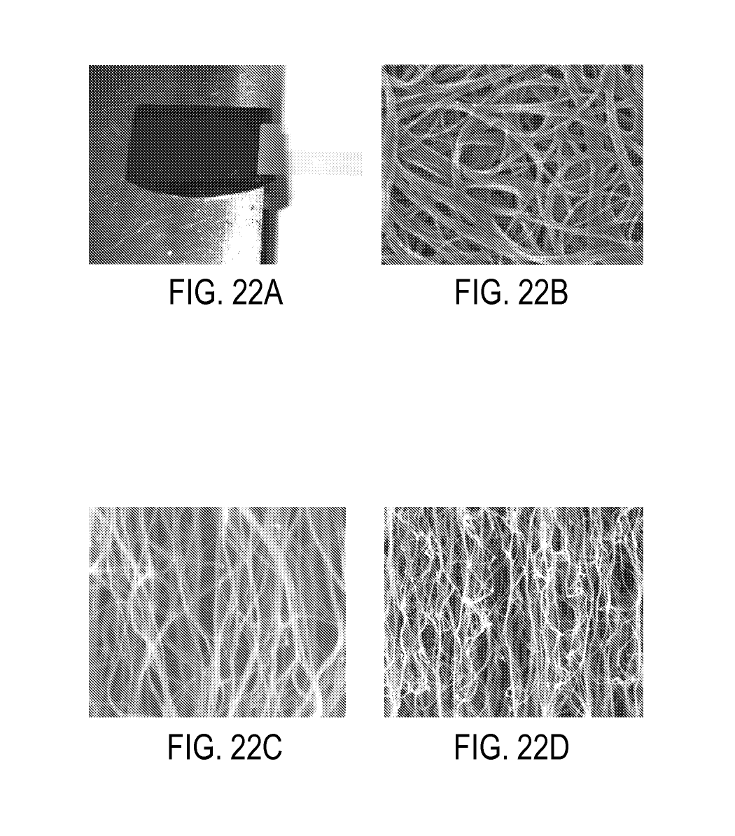

CNT sheets are used to replace traditional TCOs as anodes. They significantly simplify the fabrication process and reduce the cost. FIG. 7B shows a single OLED with CNT sheet anode, instead of ITO. The CNTs are transferred directly from free standing substrate holders onto the device (FIG. 11). SEM images of SWCNT and MWCNT are shown in FIG. 22 after the densification process. A layer of PEDOT:PSS is used to planarize the surface prior the deposition of a hole transport layer such as TPD, m-MTDATA or NPD. An additional advantage of the use of CNT is the fabrication of devices with inverted configuration. Inverted devices have the CNT electrode is placed on top of the light emitting layer and the cathode is fabricated in the bottom.

FIG. 7C illustrates an inverted device. In the beginning, a non-transparent cathode may be deposited on the substrate. The cathode is usually made of metals with low work-function such as Al, Ag, or Mg/Ag alloy. To increase the efficiency of the device an additional electron injecting layer (such as ZnO) may be used. Next, the polymeric or small molecule organic emissive layer is deposited. Finally, the CNT anode is fabricated on top of a hole injecting layer by laminating the CNT sheet from free standing holders onto the device. Prior the deposition of the CNT sheet, a layer of hole injecting material is required (such as PEDOT:PSS, MoO₃ etc). A transparent OLED can be fabricated by substituting the non-transparent cathode with a TCO (such as ITO) or a second CNT sheet and an electron injection layer as CsCO₃, Bphen, Ca, ZnO, CsF or LiF.

An embodiment of the claimed invention is directed to parallel tandem OLEDs with two complimentary colors. FIG. 8 shows a parallel tandem device consisted by two emissive units. The bottom unit of the tandem is similar device to the one shown in FIG. 7C. The CNT sheet forms an interlayer between the transparent inverted bottom OLED and the top conventional OLED. The parallel tandem device OLED device comprises a yellow emitting device with MEH-PPV as the active layer and a blue emitting PFO device. The device was fabricated on a transparent ITO coated substrate. A thin layer of cesium carbonate (Cs₂CO₃) was spin casted on the ITO to convert into a cathode to facilitate the injection of electron to the bottom MEH-PPV emissive layer. Subsequently, a layer of molybdenum oxide (MoO₃) was evaporated on top of the MEH-PPV layer and before transferring the CNT sheet to form the interlayer (common anode) of the tandem OLED. A layer of PEDOT:PSS was spin casted on CNT interlayer common anode to planarize the surface before the deposition of the second emitting layer. The blue emitting PFO polymer was used for the top unit of the tandem. Finally, a second cathode was fabricated by depositing a thin layer of Cs₂CO₃ followed by a layer of aluminum.

The device presented in FIG. 8 is comprises of two polymer OLED subunits and has three electrodes (a common anode transparent interlayer and two cathodes). The bottom unit can be selectively operated using a small voltage V₁ between the bottom cathode and the interlayer. In this case, orange emission is observed from MEH-PPV. Respectively, operation of the top unit by a separate small voltage V₂ results in blue emission from PFO. Individual and combined device operation results to emission at any point in between as shown at the CIE coordinate (chromaticity) chart in FIG. 8. The individually controlled devices may be driven to tune the emission to any color between the edge points. The combination of blue and yellow-red colors can achieve white light emission.

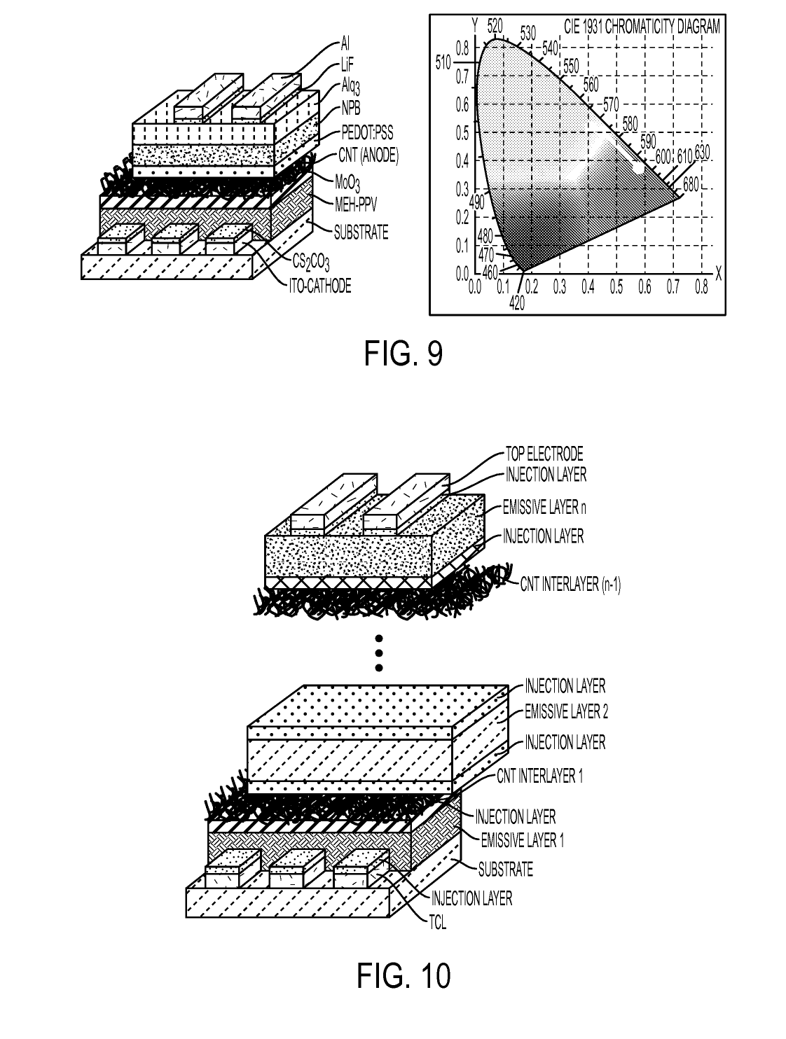

In addition, FIG. 9 illustrates a hybrid parallel tandem devices comprising a polymer OLED subunit and a small molecule OLED subunit. The color emission of the tandem is a combination of the yellow MEH-PPV emitting bottom unit and green emitting Alq₃ unit. The device was fabricated on a transparent ITO coated substrate. A thin layer of cesium carbonate (Cs₂CO₃) was spin casted on the ITO cathode ITO into a cathode and to facilitate the injection of electron to the bottom MEH-PPV emissive layer. Subsequently, a layer of molybdenum oxide (MoO₃) was evaporated on top of the MEH-PPV layer and before transferring the CNT sheet to form the interlayer (common anode) of the tandem OLED. A layer of PEDOT:PSS was spin casted to planarize the surface before the deposition of the second emitting layer. In contrast to the device described in the first example, the top unit in this case is a small molecule OLED. A hole transport layer (HTL) of NPD was deposited before the green emitting layer of Alq3. Finally, a second cathode was fabricated by the thermal evaporation of EIL LiF and Al through a shadow mask. Other electron injecting layers of Cs₂CO₃, CsF, ZnO can be used to enhance device performance.

The device presented in FIG. 9 comprises two OLED subunits and has three electrodes (a common anode interlayer and two cathodes). The bottom unit can be selectively operated by addressing the bottom cathode and the interlayer with low V₁ voltage. In this case, orange emission is observed from MEH-PPV. Respectively, operation of the top unit with low V₂ voltage results in green emission from the Alq3 layer. Individual and combined device operation results in emission at any point in between as shown at the CIE coordinate chart in FIG. 9. The individually controlled devices may be driven to tune the emission to any color between the edge points.

The developed concept claimed herein is not limited to a tandem OLED consisted with two or three subunits but may be extended to multi unit tandems. A monolithic parallel tandem OLED with multiple sub units is shown in FIG. 10. The interlayers are either a common anode or common cathode of the respective sub units on its top or bottom. The role of the interlayers will be relative to the design of the multi-unit monolithic parallel tandem OLED and the interlayer functionality need to alternate in polarity as the device is fabricated. The design of parallel tandem OLEDs may be applied to achieve emission of any color with the combination of subunits with the appropriate active organic EML layers of a proper color emission.

### WORKING EXAMPLES

### Example 1

The process of dry-drawing of CNT sheets has been discovered by scientists at the Nanotech Institute of The University of Texas at Dallas and has been improved further by several groups, including those who emphasize the drawing of CNT yarns and fibers. Synthesis of CNT is done inside a three zone furnace with two inch diameter quartz tube will be utilized for Chemical Vapor Deposition (CVD) of CNT. Acetylene gas is inserted in a reactor at about 700° C. during the growth process. This CVD furnace will grow multi-walled carbon nanotubes (MWCNT) on the silicon wafer with iron catalyst deposited by e-beam deposition. After the CNT forest is grown on the silicon wafer, the forest can be pulled out and transferred as free standing CNT sheets. A CNT forest grown on the surface of a Si substrate is shown FIG. 11. A CNT sheet is then pulled off the forest and a continuous strand is formed. The CNT sheet it placed free standing on the CNT sheet holder as for storage and transfer to any surface. The CNT sheet may then easily be laminated on top of the OLED device bare substrate or on top of any layer that is part of an OLED structure. FIG. 22A shows a photograph of CNT forest and the process of pulling a CNT sheet.

### Example 2

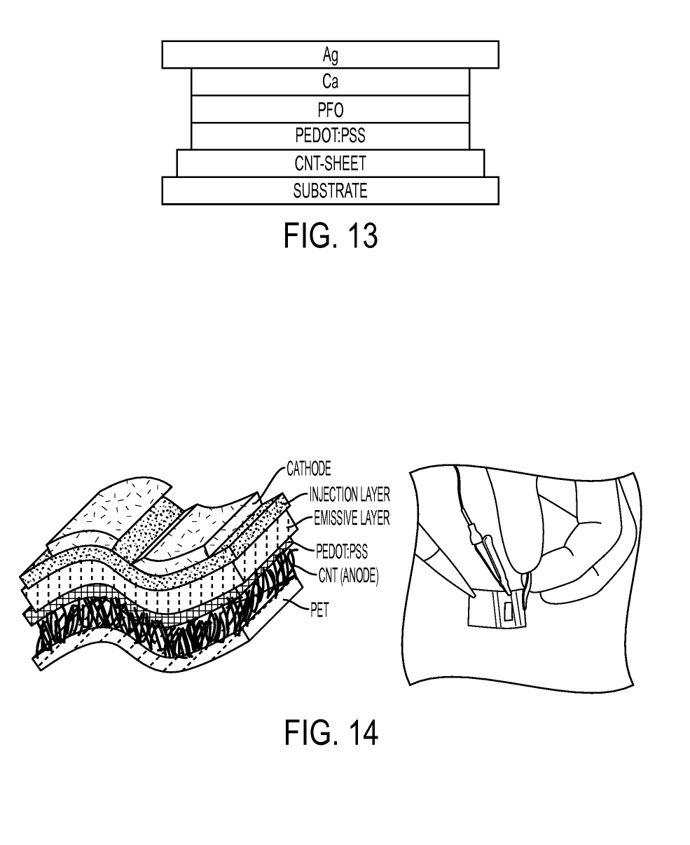

FIGS. 12 and 13 illustrate transparent OLEDs with CNT sheets. A transparent bottom cathode, similar to the ones described above, is fabricated on glass substrate. An emissive layer is deposited and then the CNT sheet is deposited to form the anode. In FIG. 12, the device structure is very similar to the bottom unit of tandem OLED, except that CNTs are not required to be placed between two hole injecting layers. FIG. 13 demonstrates another structure for transparent OLED devices. In this configuration, the CNT sheets are transferred on top of the transparent substrate. Next, a planarizing layer of PEDOT:PSS is spin casted before the active layer. The cathode is fabricated by deposition of transparent cathode on top that can be fabricated by bilayers of electron injecting materials (Ca, Mg, LiF, Cs, Bphen, Cs₂CO₃) and a metal (Ag,Al,Ni). A second layer of CNTs may be applied instead of the metal layer.

### Example 3

Flexible substrates are compatible with CNT sheets for flexible OLEDs. FIG. 14 illustrates a similar device to Example 2 (FIG. 13) but on a flexible substrate. Traditional transparent conductive oxides (such as ITO) are brittle and may crack under tension. CNT sheets have excellent mechanical and electrical properties and are excellent alternatives to ITO. CNT sheets are transferred on a polyethylene terephthalate (PET) substrate and the resulting surface is planarized prior the deposition of the emissive layer. An electron injection layer and the cathode are added to conclude the fabrication. The parallel tandem architecture of the claimed invention is compatible with flexible substrates and devices as shown in FIG. 10 can be fabricated in the same way.

### Example 4

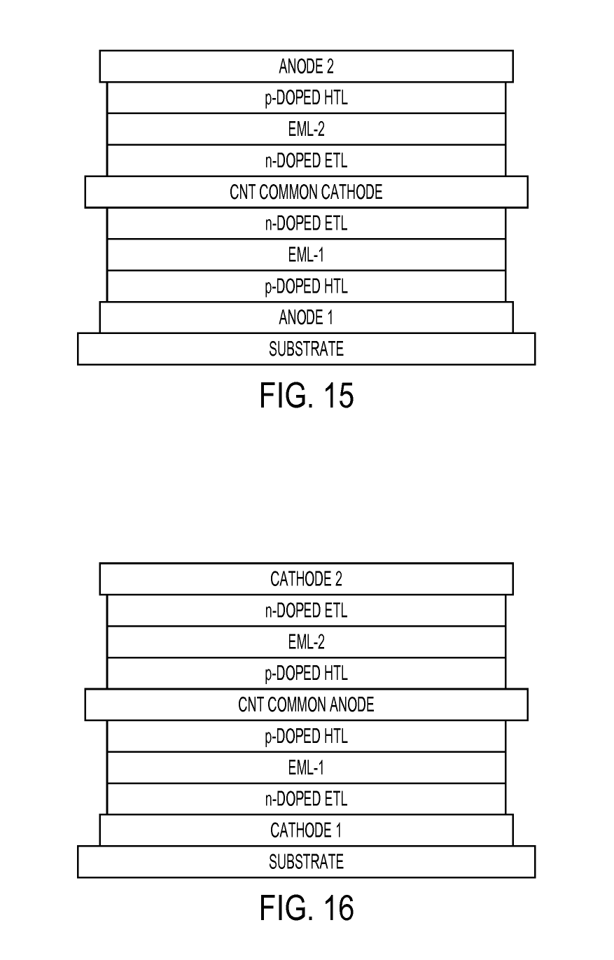

Recent advances have shown OLED devices with increased performance and lifetime that incorporate doped charge transport layer. In the simplest case, an OLED may comprise two electrodes and an active layer that generates the light emission. In reality, multiple layers are need to produce efficient devices. The use of dedicated transport and injection layers improve injection and balance the device operation. Furthermore, dopants are incorporated into such layers for additional improvement. The parallel tandem OLED architecture is compatible with such a doped layer. FIG. 15 shows a device that employs such layers. On top of a transparent substrate an anode of ITO or CNT sheets is fabricated. Next, a hole transport layer is deposited either be thermal evaporation or spin casting. Traditional hole transport layers such as NPB, TPD, DMFL-TPD, TAPC, TFB are many times doped to achieve higher work function or conductivity with dopants as F4-TCNQ or molybdenum oxides. The active layer of the bottom unit or the parallel tandem OLED is fabricated prior to the electron transport layer that is commonly made of BCP, Bphen, BAlq, ZnO, Alq₃. Popular dopants and electron injection layers used are LiF, Li, AOB, Ca, Cs₂CO₃ and CsF. The CNT sheets are placed next to form the common cathode interlayer. The top unit of the tandem OLED is fabricated with layers in inverse order to the bottom. In addition, FIG. 16 shows a parallel tandem OLED with a common anode that also utilizes doped charge transport layers.

### Example 5

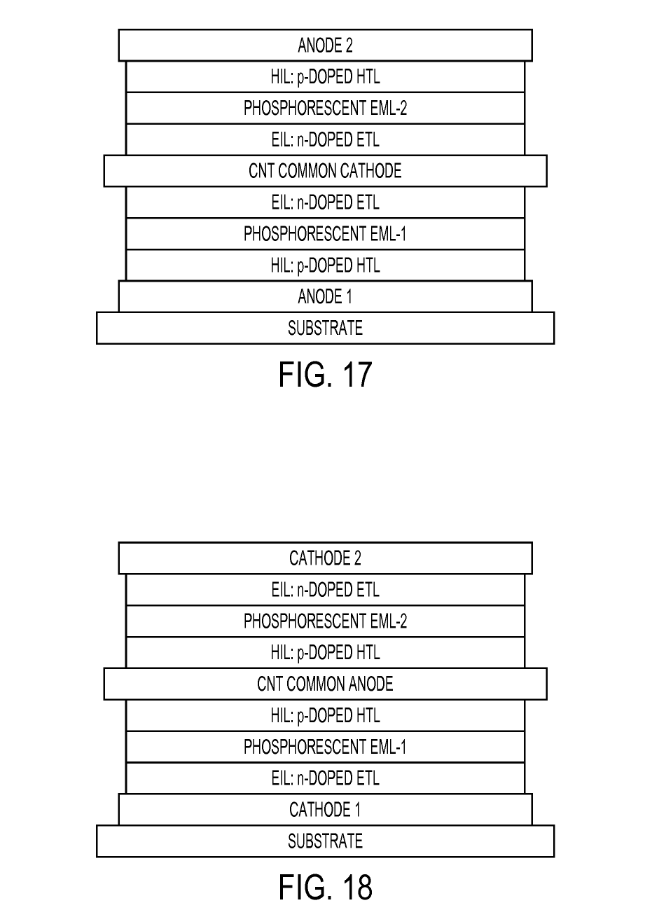

A wide variety of phosphorescent emissive organic materials for OLEDs have been reported and investigated by the scientific community. The claimed invention of parallel tandem OLED architecture can be applied to improve those devices. FIG. 17 shows a parallel tandem OLED with doped transport layers and phosphorescent emissive layers. An anode is deposited on the substrate, followed by a HIL layer, as described in Example 4. The phosphorescent emissive layer comprises a host material, such as CBP, TCP, TCTA, CTP, and a dopant to generate light emission. Various dopants are used to achieve emission in different colors. Examples of common green dopants are Coumarin, Ir(ppy)₃, TPA, blue dopants are DPAVBi, DPAVB and red dopants are DCM, DCJT. An inverted parallel tandem OLED with common cathode interlayer is shown in FIG. 18.

### Example 6

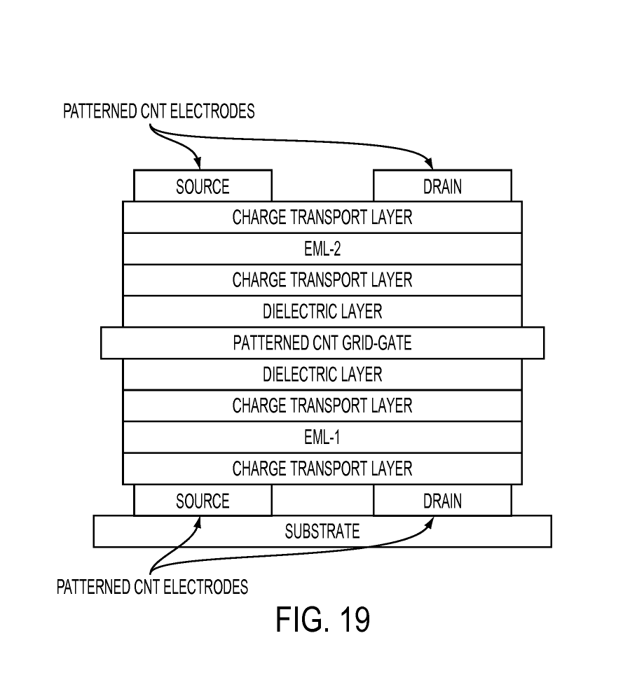

A potential application of nano-carbon structures is the fabrication of electrode and common interlayers in organic light emitting transistors (OLET). An example of a tandem OLET device is shown in FIG. 19. Patterned CNT sheets are used as source and drain electrodes, followed by an injection/transport and emissive layer of an OLED. The CNT interlayer is encapsulated between two insulating layer (for example AlO₃, PMMA) and is the gate electrode of the OLET. Application of a voltage at the CNT gate causes charges to accumulate charges inside the emissive layer and causes the OLED to turn on. Electron and holes are injected through the source and drain electrodes and recombine to emit light. The top unit of the tandem OLED is comprised of as emissive layer and top source and drain electrodes.

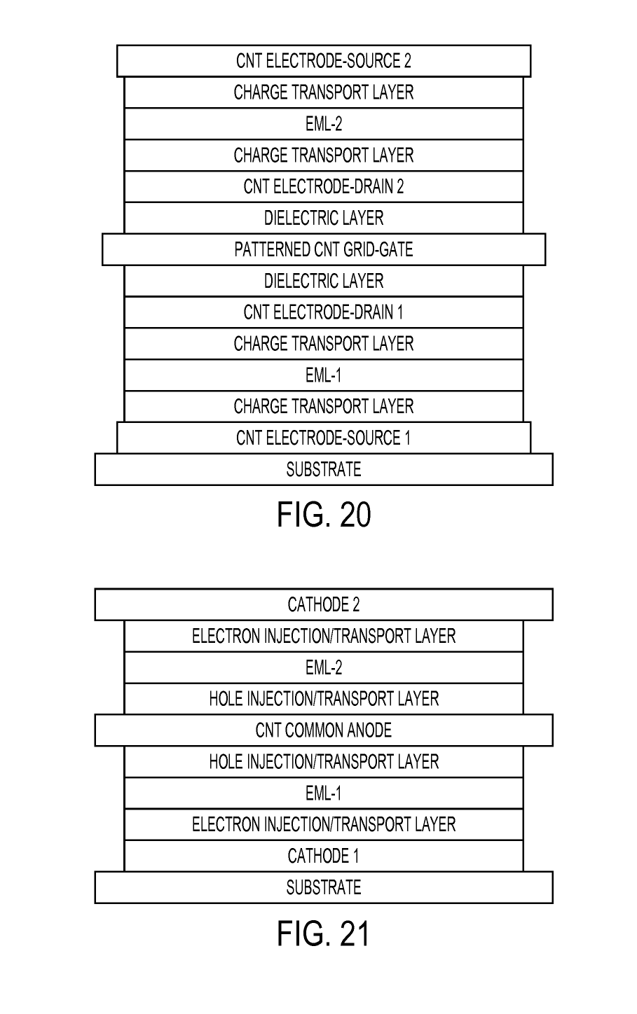

An additional tandem OLET with vertical architecture is shown in FIG. 20. In this case the source and drain electrodes are fabricated with CNT sheets in a similar way to cathodes and anodes. Charges are injected into the emissive layer, vertically transport and recombine.

### Example 7

OLEDs are usually driven by applying a direct current (DC) voltage across the electrodes. Operation with alternating current (AC) voltages has also being reported. Blends of different emissive materials are used as active materials and special redox injecting layers facilitate injection in both AC and DC regimes. The advantages of AC operation include tuning of color emission and improved lifetime. FIG. 21 represents a parallel tandem OLET with CNT interlayer with subunits that can be driven by application of AC voltages.

### Example 8

An example of the parallel tandem OLED device comprising three units with similar architecture to the one shown in FIG. 6 is described here and has the following structure. A TCO or CNT sheet is used as the bottom anode electrode. A layer of PEDOT:PSS or MoO₃ enhances hole injection to first active layer. A layer of MEH-PPV is the first emissive layer (EL-1). The common interlayer between first and second sub units is fabricated by CNT sheers (or ITO) that have been inverted with the addition of low work functions layers such ZnO or Cs₂CO₃. The transparent inverted interlayer is followed by a second emissive layer of blue emitting PFO layer. Prior to the fabrication of the third unit, a second interlayer is needed that functions as common anode. The fabrication of such interlayer is described in the devices shown in FIG. 8 and FIG. 9. A layer of CNT sheets is placed between high work function material such as PEDOT:PSS and MoO₃. The third and final emissive layer is deposited by thermal evaporation of hole transport NPB and green emissive layer of Alq₃. The top electrode made of a bilayer of LiF and Al is also deposited by thermal evaporation and through a shadow mask. The emissive layers of this example have been selected from widely used organic material and emit in complimentary color and generate light mission close to white. Devices with three complimentary color have been presented previously, wherein the interlayer for electron injection (cathode) was fabricated with Ag:Mg alloys and ITO for hole injection (anode). Embodiments of the present invention permit the utilization of materials such as ITO or CNT sheets in inverted interlayer. Specifically, inversion layers of ZnO, CsF, Cs₂CO₃ or Mg can be combined with high work function metals or other carbon nanostructures to fabricated common cathodes.

1. A stacked organic light-emitting device comprising:
a first electrode;
a second electrode;
at least two light emitting units that are located between the first electrode and the second electrode;
at least two injection layers comprising a charge (electron or hole injecting element); and
an interlayer electrode, wherein the interlayer electrode comprises an optically transparent electrically conductive layer, such as carbon nanotubes, and is located between the at least two injection layers of similar polarity charge that contact the at least two light emitting units; and
wherein said at least two injection layers contact the interlayer electrode and each of the at least two light emitting units.

2. The stacked organic light-emitting device of claim 1, wherein the charge injection layers contacting plus biased interlayer (an anode interlayer) are a hole injecting elements such as PEDOT PSS or MoO₃.

3. The stacked organic light-emitting device of claim 1, wherein the charge injection layers contacting minus biased interlayer (a cathode interlayer) are an electron injecting elements such as Cs₂CO₃ or ZnO.

4. The stacked organic light-emitting device of claim 1, wherein the first electrode is disposed on a transparent substrate.

5. The stacked organic light-emitting device of claim 1, wherein the first electrode is an anode, such as ITO or CNT.

6. The stacked organic light-emitting device of claim 1, wherein the first electrode is optically transparent.

7. The stacked organic light-emitting device of claim 6, wherein the first electrode is formed of ITO.

8. The stacked organic light-emitting device of claim 6, wherein the first electrode is formed of carbon nanotubes.

9. The stacked organic light-emitting device of claim 1, wherein the second electrode is a cathode.

10. The stacked organic light-emitting device of claim 1, wherein the second electrode is transparent.

11. The stacked organic light-emitting device of claim 10, wherein the second electrode is formed of carbon nanotubes, modified into a cathode by thin layers of CsCo3 or ZnO.

12. The stacked organic light-emitting device of claim 6, wherein the second cathode electrode is formed of ITO modified by thin Cs₂CO₃ film.

13. A method of making a monolithic multi junction OLED device capable of emitting light through a top electrode of such device comprising the steps of:
(a) providing a substrate and an anode over the substrate;
(b) providing an emissive layer disposed over the anode;
(c) providing first and second layers over the emissive layer with the first layer being in contact with the emissive layer and having a compound that includes an hole injecting element (such as PEDOT:PSS or MoO₃) and the second layer playing a role of charge injecting interlayer electrode made of mechanically strong transparent and conducting nano-carbon structures, such as single wall carbon nanotube (SWCNT) sheets, multi wall carbon nanotube (MWCNT) sheets, graphene, graphene ribbons or similar other nano-carbon structures in contact with the first layer, making the bottom sub-cell of OLED tandem; and
(d) providing on top of transparent conducting interlayer electrode another set of layers (hole injecting (such as p-doped hole transport layer, second emissive layer, electron injection layer (such as n-doped electron transport layer) and top electrode) comprising altogether a top sub-cell of the OLED monolithic multi junction tandem.

14. (canceled)

15. The method of claim 13 wherein the top and bottom sub-cells are connected in parallel and the common charge collecting interlayer is a common anode.

16. The method of claim 13 wherein the top and bottom sub-cells are connected in parallel and the common charge collecting interlayer is a common cathode.

17-19. (canceled)

20. The stacked organic light-emitting device of claim 6, wherein the number of subunits in the stack is greater than three, and wherein the subunits are created by sequentially adding subunits comprising the proper sequence of interlayers.

21. The method of claim 13 wherein the anode is a metal, or a metal oxide, or a transparent conductive oxide, or nano-carbon structures such as SWCNT and MWCNT sheets.

22. (canceled)

23. The method of claim 13 wherein the interlayer is nano-carbon structures such as SWCNT and MWCNT sheets.

24. (canceled)

25. The method of claim 13 wherein the cathode comprises nano-carbon structures such as SWCNT and MWCNT sheets.

26. The method of claim 13 wherein the top and bottom sub cell emissive layer materials are chosen with complimentary colors for light emission with specific color.

27. (canceled)

28. The method of claim 13 wherein the top and bottom sub cells are driven with different current densities by separately applied continuous or pulsed voltage to each sub-cell for tuning of emitted light chromaticity.

29. (canceled)

30. The method of claim 13 wherein the substrate is flexible

31-34. (canceled)
